(19) United States
(12) Patent Application Publication
(10) Pub. No.: US 2014/0070328 A1
(43) Pub. Date: Mar. 13, 2014

(54) SEMICONDUCTOR DEVICE AND METHOD OF FABRICATING THE SAME

(71) Applicants: Masakazu Goto, Halfmoon, NY (US); Akira Hokazono, Clifton Park, NY (US)

(72) Inventors: Masakazu Goto, Halfmoon, NY (US); Akira Hokazono, Clifton Park, NY (US)

(73) Assignee: TOSHIBA AMERICA ELECTRONIC COMPONENTS, INC., Irvine, CA (US)

(21) Appl. No.: 13/611,040

(22) Filed: Sep. 12, 2012

(51) Int. Cl. H01L 27/088; H01L 21/8234

(52) U.S. Cl. 257/401; 438/283; 257/E27.06; 257/E21.616

(57) ABSTRACT

Semiconductor devices and methods of fabricating semiconductor devices are provided. Two or more layers can be formed on a silicon substrate, wherein one or more of the layers are used for controlling an isolation recess. A first layer can comprise a first material and a second layer can comprise a second material.

### FIELD

The following description relates generally to semiconductor devices and methods of fabricating semiconductor devices.

### BACKGROUND

As transistor design is improved and evolved, the number of different types of transistors continues to increase. Multi-gate fin field effect transistors (e.g., FinFETs) are developed to provide scaled devices with faster drive currents and reduced short channel effects over planar FETs. One feature of the FinFET is that the conducting channel is wrapped around a thin silicon “fin,” which forms the body of the device. The dimensions of the fin can determine the effective channel length of the device. The term “FinFET” is used generically to describe any fin-based, multi-gate transistor architecture regardless of the number of gates. Examples of multi-gate fin field effect transistors include double-gate FinFETs and tri-gate FinFETs.

Double-gate FinFETs are FETs in which a channel region is formed in a thin semiconductor fin. The source and drain regions are formed in the opposing ends of the fin on either side of the channel region. Gates are formed on each side of the thin semiconductor fin, and in some cases, on the top or bottom of the fin as well, in an area corresponding to the channel region. FinFETs are generally a type of double-gate FinFETs in which the fin is so thin as to be fully depleted.

Tri-gate FinFETs have a similar structure to that of double-gate FinFETs. The fin width and height of the tri-gate FinFETs, however, are approximately the same so that gates can be formed on three sides of the channel, including the top surface and the opposing sidewalls. The height to width ratio is generally in the range of 3:2 to 2:3 so that the channel will remain fully depleted and the three-dimensional field effects of a tri-gate FinFET will give greater drive current and improved short-channel characteristics over a planar transistor.

### BRIEF DESCRIPTION OF THE DRAWINGS

FIGS. 1A through 1D illustrate a schematic representation of a FinFET structure.

FIGS. 2A through 2D illustrate an example, non-limiting schematic representation of a FinFET structure, according to an aspect.

FIGS. 3A through 3C illustrate a schematic representation of another FinFET structure.

FIGS. 4A through 4C illustrate another example FinFET structure, which can be a recessed channel bulk FinFET.

FIGS. 5A through 5D illustrate a semiconductor structure.

FIGS. 6A through 6D illustrate an example, non-limiting schematic representation of a semiconductor structure, according to one or more of the disclosed aspects.

FIGS. 7A to 7D illustrate an example, non-limiting schematic representation of a semiconductor device that can be fabricated while controlling an isolation recess, according to an aspect.

FIG. 8 illustrates an example, non-limiting method for controlling fabrication of a semiconductor device, according to an aspect.

FIG. 9 illustrates an example, non-limiting method for fabricating a semiconductor device, according to an aspect.

FIG. 10 illustrates an example, non-limiting method for fabricating a semiconductor device while controlling an isolation recess, according to an aspect.

FIGS. 11A through 25C illustrate an example, non-limiting process flow for fabricating a device, according to an aspect.

FIGS. 26A through 28C illustrate an alternative process flow for fabricating a semiconductor device, according to an aspect.

### DETAILED DESCRIPTION

The embodiments disclosed herein provide various techniques related to semiconductor manufacturing processes and solutions. In particular, the aspects disclosed herein relate to controlling an isolation recess and reducing the occurrence of device failure and variations.

FinFET (Double-gate, Tri-gate, all around-gate, and so forth) devices are candidates for complementary metal-oxide-semiconductor (CMOS) device structure in 22 nm technology node and beyond. This is due to these devices having good cut-off characteristics and better scalability by multi-gate mode operation.

In FinFET devices, fin to fin isolation is necessary. The isolation can be formed from a silicon dioxide (SiO2) layer. The SiO2 layer can be easily recessed by following various processes that are generally known and will not be described in detail herein for purposes of simplicity in describing the various aspects. The recessing of the SiO2 layer can contribute to device failure and variations. Various aspects disclosed herein utilize the insertion of one or more other dielectric isolation layers into the SiO2 isolation layer. For example, silicon nitride (SiN) can be utilized as one or more of the other dielectric isolation layers. The insertion of the one or more other dielectric isolation layers can control the isolation recess and, therefore, can reduce device failures and variations.

In an implementation, provided is a semiconductor structure, comprising a semiconductor substrate comprising a plurality of fins. The semiconductor structure can also comprise a multi-layer structure over the semiconductor substrate. The multi-layer structure can comprise a first layer and at least a second layer. The first layer can comprise a first material and the second layer can comprise a second material different from the first material. Further, the semiconductor structure can comprise an epitaxial source/drain portion. The second layer can be formed on the first layer and the second layer can contact a bottom of the epitaxial source/drain portion. According to an aspect, the first material can comprise silicon dioxide (SiO2) and the second material can comprise silicon nitride (SiN).

According to another implementation, provided is a semiconductor structure comprising a semiconductor substrate comprising a plurality of fins and a replacement metal gate region. The semiconductor substrate can also comprise a multi-layer structure over the semiconductor substrate. The multi-layer structure can comprise a first layer, a second layer, and at least a third layer. The first layer and the third layer can comprise a first material and the second layer can comprise a second material different from the first material. Further to this implementation, the second layer can be formed between the first layer and the third layer. Further, the second layer can be formed to contact a bottom of a gate dielectric. In accordance with an aspect, the first material can comprise silicon dioxide (SiO2) and the second material can comprise silicon nitride (SiN).

According to a further implementation, provided is a method that can comprise employing a processor to facilitate execution of code instructions retained in a memory device, the processor, in response to execution of the code instructions, can cause a system to perform operations. The operations can include forming a semiconductor substrate. The operations can also include forming a first layer comprising a first material over the semiconductor substrate and forming a second layer over the first layer. The second layer can be formed to contact a bottom of a gate dielectric. Further, the second layer can comprise a second material, different from the first material. The operations can also include forming a third layer over the second layer. The third layer can comprise the first material. The operations can further include forming a fourth layer over the third layer. The fourth layer can be formed to contact a bottom of an epitaxial source/drain region. The fourth layer can comprise the second material. Further, the third layer can be formed between the second layer and the fourth layer. The operations can also include forming a replacement metal gate.

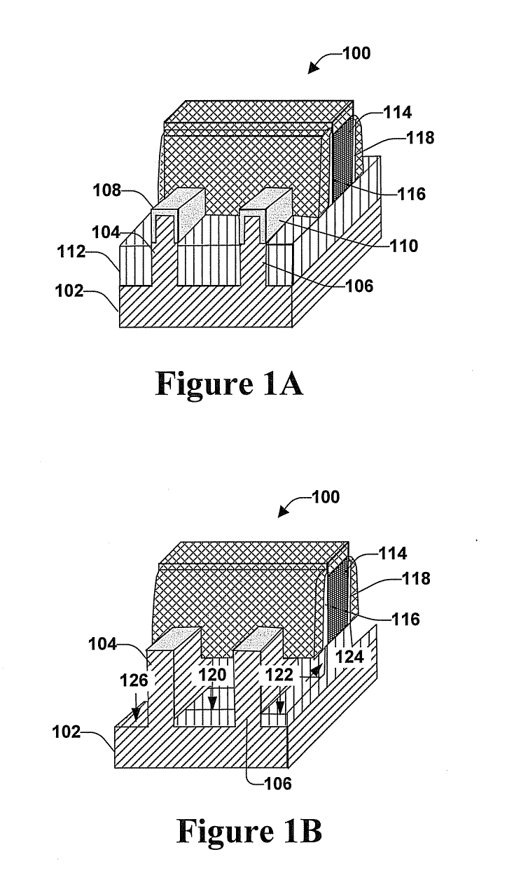

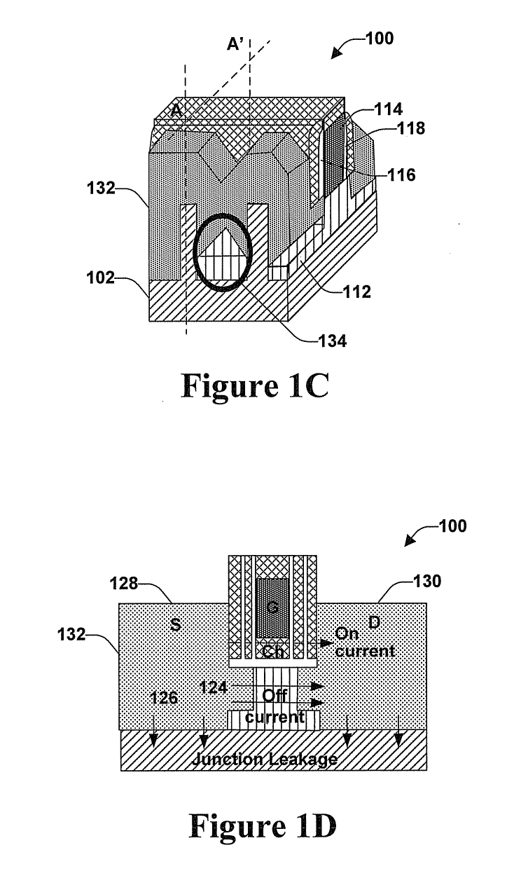

Referring initially to FIGS. 1A through 1D, illustrated is a schematic representation of a FinFET structure 100. FIG. 1A illustrates a three-dimensional representation of the FinFET structure 100 after spacer formation. During semiconductor processing, spacers can be utilized for ion implantation. For example, after gate formation, source/drain regions near the gate can be lightly doped and spacers can be formed adjacent to the gate after the source/drain dope implantation. In some cases, the spacers can be formed before the source/drain dope implantation. Thereafter, the spacers can be removed and a lightly-doped implant region can be formed in place of the removed spacers.

The FinFET structure 100 can comprise a silicon substrate 102 on which fins are formed, illustrated as a first fin 104 and a second fin 106. Although the FinFET structure 100 is illustrated as having two fins, it should be understood that more than two fins could be formed on the silicon substrate 102. Each fin can have a protection layer (e.g., Dummy Oxide). For example, a first protection layer 108 can be formed on the first fin 104 and a second protection layer 110 can be formed on the second fin 106.

A layer, which can be referred to as a local isolation layer 112, can be formed on the silicon substrate 102. In an example, the local isolation layer can comprise silicon dioxide (SiO2). Also illustrated are the gate region 114 and the spacers, wherein a first spacer 116 is located on a first side of the gate region 114 and a second spacer 118 is located on a second side of the gate region 114.

FIG. 1B illustrates the FinFET structure 100 after a source/drain (S/D) epitaxial (EPI) pre-clean operation. In an example, the EPI pre-clean operation can be performed using a dilute hydrofluoric (DHF) acid wet etch operation. During a fin to fin etch EPI operation (e.g., EPI pre-clean operation), a source region can be widened to create the fin. For example, the etch operation can remove the silicon dioxide (e.g., the local isolation layer 112). However, the local isolation recess (formed by etching the local isolation layer during, for example, a DHF operation) could induce various issues associated with the semiconductor device.

For example, as indicated by arrows 120 and 122, recess depth variation can be caused by the local isolation recess. For example, the depth at 120 is less than the depth at 122. This recess depth variation can induce S/D depth variation.

In another example, as indicated by arrow 124, the etch operation can lead to local isolation undercut, where the recess extends at least partially under the S/D region. The local isolation undercut can induce S/D encroachment. For example, the etch operation could cause an undercut local isolation distance under the spacer (e.g., first spacer 116), or worst case under the gate region 114, which can cause the S/D encroachment. The S/D encroachment can create short channel degradation.

In a further example, as indicated by arrow 126, the etch operation can cause the silicon substrate 102 to be exposed. In the case of a bulk FinFET, an exposed silicon substrate can induce junction leakage. In some cases, the junction leakage can be severe. For example, if there is too much (e.g., high) etch occurring at one or more portions of the local isolation layer, the entire local isolation layer at those potion(s) could be removed and exposure of the silicon substrate can occur (as indicated by arrow 126). This can create problems since there should be some isolation (e.g., at least some of the local isolation layer) between the epitaxial layer and the silicon substrate 102. If the epitaxial layer and the silicon substrate 102 layer are in contact, junction leakage can occur.

FIG. 1C illustrates the FinFET structure 100 after a source drain (S/D) epitaxial (EPI) operation and FIG. 1D illustrates a cross-section of the FinFET structure 100 taken along line A-A′ of FIG. 1C. Illustrated are the source region 128 and the drain region 130. The S/D EPI operation can create voids under a doped S/D EPI region 132, as indicated by the circled portion 134. Thus, one or more portions of the local isolation layer 112 (e.g., SiO2) could remain due to the etch not being high enough. Therefore, in some cases, the S/D-EPI operation could cause a S/D EPI facet, which can induce a void underneath the doped S/D-EPI region (see circled portion 134). In these cases, the FinFET structure could exhibit high-junction leakage and/or high-off current (punch thru).

The deficiencies of semiconductor devices and the fabrication of semiconductor devices described herein are merely intended to provide an overview of some of the problems that can be encountered, and are not intended to be exhaustive. For example, other problems with semiconductor devices and the fabrication of semiconductor devices and corresponding benefits of the various non-limiting embodiments described herein should become apparent upon reading this detailed description.

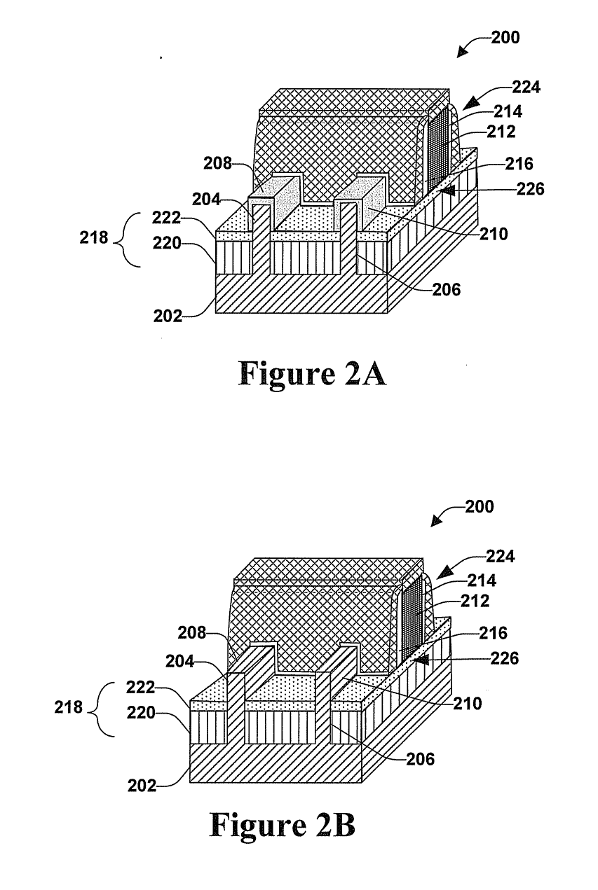

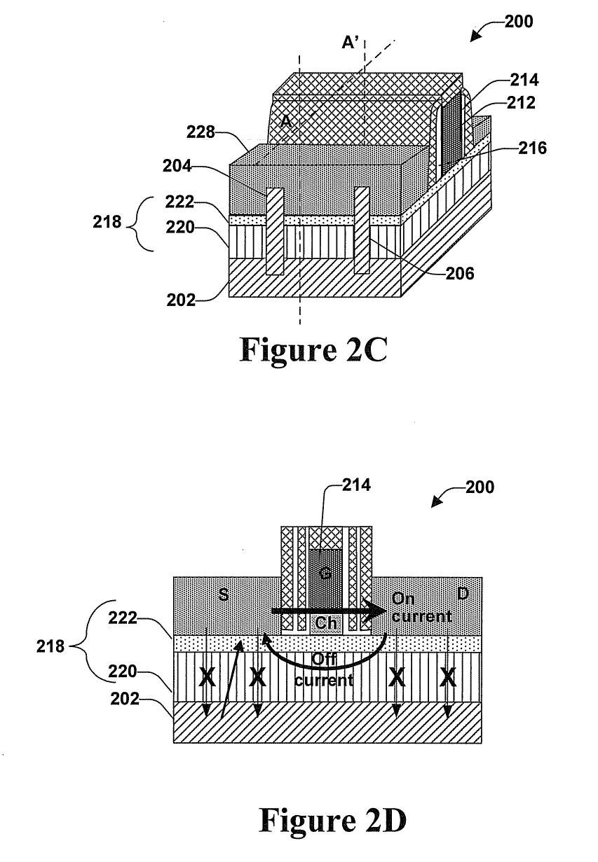

FIGS. 2A through 2D illustrate an example, non-limiting schematic representation of a FinFET structure 200, according to an aspect. FIG. 2A illustrates a three-dimensional representation of the example FinFET structure 200 after spacer formation, according to an aspect. The FinFET structure 200 comprises a silicon substrate 202 on which a first fin 204 and a second fin 206 are formed. Although two fins are shown, in some cases, more than two fins can be formed on the silicon substrate 202. Each fin can have a protection layer (e.g., Dummy Oxide). For example, a first protection layer 208 can be formed on the first fin 204 and a second protection layer 210 can be formed on the second fin 206.

The FinFET structure 200 also includes a gate portion 212. Further the FinFET structure 200 can include at least a first spacer 214, located on a first side of the gate portion 212, and at least a second spacer 216 located on a second side of the gate portion 212.

A multi-layer structure 218 can be formed on the silicon substrate 202. The multi-layer structure 218 can comprise at least two layers, illustrated as a first dielectric layer 220 and at least a second dielectric layer 222. The first dielectric layer 220 and the second dielectric layer 222 can be local isolation layer. In an implementation, the first dielectric layer 220 can comprise a first material and the second dielectric layer 222 can comprise a second material. The first material and the second material can be different materials. Both the first material and the second material can be chosen from a set of materials that provide fin-to-fin isolation. In an implementation, the first material can be silicon dioxide (SiO2) and the second material can be silicon nitride (SiN).

As illustrated, according to an implementation, the first layer can comprise a first thickness and the second layer can comprise a second thickness. The second thickness can be different than the first thickness. In some aspects, the first thickness is greater than the second thickness (e.g., the first layer is thicker than the second layer), as illustrated. In other aspects, the first thickness is less than the second thickness (e.g., the second layer is thicker than the first layer). In still other aspects, the first thickness and the second thickness are similar (e.g., the first layer and the second layer comprise a similar thickness).

The FinFET structure 200 can also comprise an epitaxial source/drain portion 224. The second dielectric layer 222 can be formed on the first dielectric layer 220 and, further, can be formed to contact a bottom 226 of the epitaxial source/drain portion 224. For example, the first dielectric layer 220 is in contact with the bottom 226 of the epitaxial source/drain portion 224 such that there are no other layers between the first dielectric layer 220 and the bottom 226 of the epitaxial source/drain portion 224.

FIG. 2B illustrates the FinFET structure 200 after a source/drain (S/D) epitaxial (EPI) pre-clean operation, according to an aspect. In an example, the EPI pre-clean operation can be performed using a dilute hydrofluoric (DHF) acid wet etch process. The second dielectric layer 222, which can comprise SiN, can protect the local isolation layer (e.g., the first dielectric layer 220). For example, a DHF process can be selective to SiN. Therefore, during the DHF process, the second dielectric layer 222 can stop the DHF process and prevent the etch operation from excessively removing portions of the first dielectric layer 220.

FIG. 2C illustrates the FinFET structure 200 after a source drain (S/D) epitaxial (EPI) operation and FIG. 2D illustrates a cross-section of the FinFET structure 200 taken along line A-A′ of FIG. 2C. As illustrated, the S/D EPI can be controlled. Further, there is no S/D EPI facet (e.g., there is no void underneath the doped S/D-EPI Si region 228) due to the protection provided by the second dielectric layer 222 (e.g., SiN).

As discussed above, a FinFET has the risk of fin isolation recess on a S/D region during a S/D EPI process, especially with a DHF treatment for EPI pre-clean. The fin isolation recess could cause isolation recess depth variations, isolation undercut underneath the spacer, as well as other problems. By forming the first dielectric layer and the second dielectric layer as described, the S/D EPI can be controlled (e.g., the EPI pre-clean does not attach isolation). Further, there is no S/D EPI facet due to the insertion of the second layer (e.g., a SiN layer). As compared to the structure of FIGS. 1A through 1D, the FinFET structure 200 illustrated in FIGS. 2A through 2D has low junction leakage and has a low-off current. Thus, the application of a layer (e.g., SiN layer, second layer) over the local isolation layer (e.g., SiO2 layer, first layer) can help control an isolation recess, which can help to avoid device failure and/or variations.

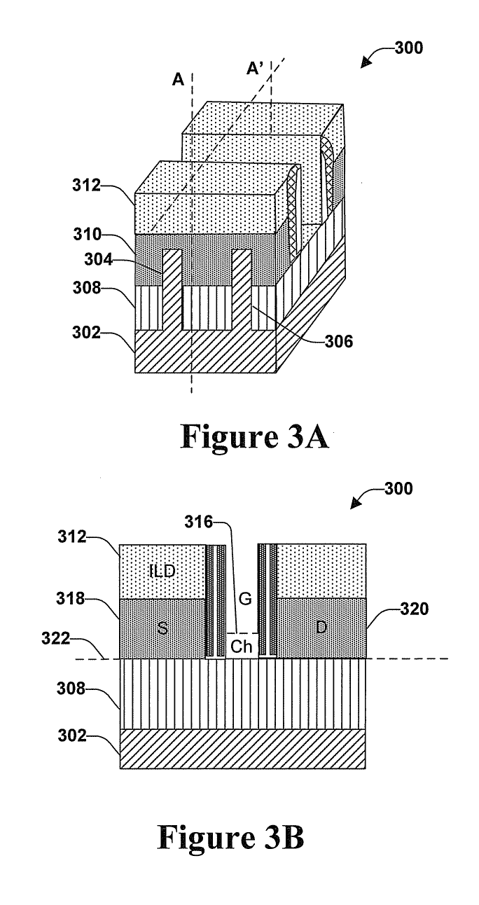

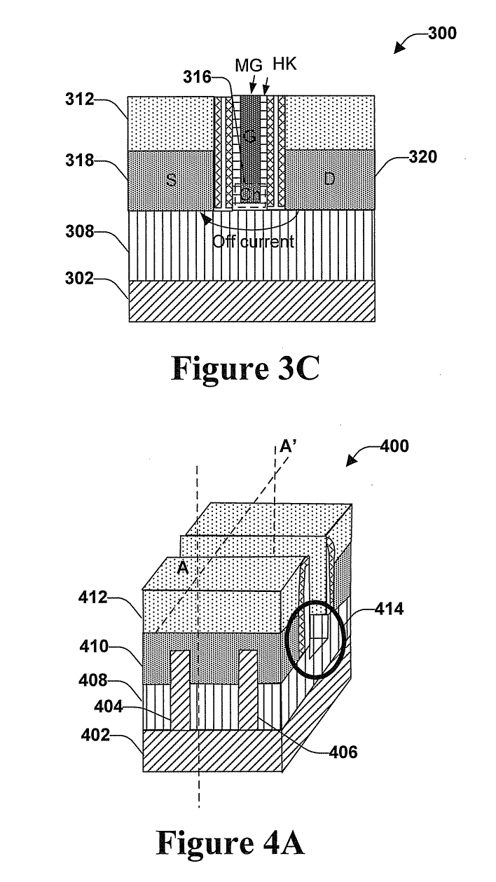

FIGS. 3A through 3C illustrate a schematic representation of another FinFET structure 300. FIG. 3A illustrates a three-dimensional representation of a FinFET structure 300 and FIG. 3B illustrates a cross-section of the FinFET structure 300 taken along line A-A′ of FIG. 3A.

The FinFET structure 300 comprises a silicon substrate 302 on which fins are formed, illustrated as a first fin 304 and a second fin 306. Although the FinFET structure 300 is illustrated as having two fins, it should be understood that more than two fins could be formed on the silicon substrate 302.

A layer, which can be referred to as a local isolation layer 308, can be formed on the silicon substrate 302. In an example, the local isolation layer can be formed with silicon dioxide (SiO2). Formed on the local isolation layer 308 can be a doped EPI-Si layer 310. An inter-layer dielectric (ILD) layer 312 can be formed over the doped EPI-Si layer 310.

After a chemical-mechanical planarization (CMP) operation, a first gate is removed from the structure. As shown in FIG. 3B, a bottom of a channel region 316, a bottom of a source region 318, and a bottom of a drain region 320 are located along the same line 322. FIG. 3C illustrates the FinFET structure 300 of 3B after a replacement metal gate operation. “MG” is the metal gate and “H K” is a to high-k gate dielectric. High temperature should be avoided with devices that include a metal gate.

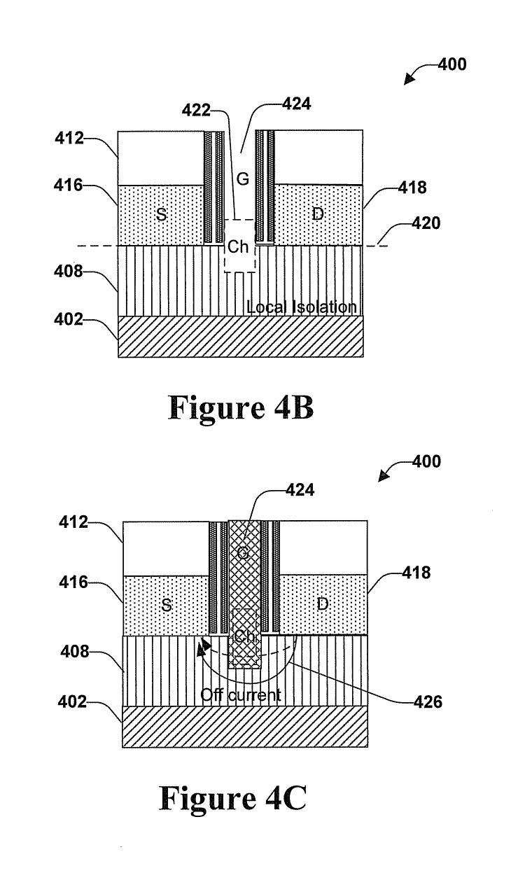

In a related concept, FIGS. 4A through 4C illustrate another example FinFET structure 400, which can be a recessed channel bulk FinFET. FIG. 4A illustrates a three-dimensional representation of the FinFET structure 400. The FinFET structure 400 comprises a silicon substrate 402 on which fins are formed, illustrated as a first fin 404 and a second fin 406. Although the FinFET structure 400 is illustrated as having two fins, it should be understood that more than two fins can be formed on the silicon substrate 402.

A layer, which can be referred to as a local isolation layer 408, can be formed on the silicon substrate 402. In an example, the local isolation layer can be formed with silicon dioxide (SiO2). Formed on the local isolation layer 408 is a doped EPI-Si layer 410. An inter-metal layer dielectric (ILD) layer 412 can be formed over the doped EPI-Si layer 410. A channel region of the FinFET structure 400 is recessed, as indicated within circle 414, as compared to the FinFET structure of FIG. 3A. Thus, the local isolation region (e.g., local isolation layer 408) is recessed as indicated within circle 414.

With the recess local isolation, the channel area can be widened, as illustrated in FIG. 4B. If the local isolation under the gate region is recessed, the channel region can be made wider. Thus, after high-k gate dielectric and metal gate deposition, a higher metal gate can be formed (as compared to FIG. 3B) since the gate material forms into the local isolation area.

Further, the bottom of a source region 416 and a bottom of a drain region 418 are located along the same line 420. However, as shown in FIGS. 4B and 4C a channel region 422 extends into the local isolation layer (e.g., local isolation layer 408) and, therefore, a bottom of the channel region 422 is below line 420. Further, a bottom line of a gate 424 is formed into the local isolation layer 408. For example, the gate 424 extends into the local isolation layer 408. This can be useful for reducing off current because the source to drain distance is longer than for other FinFET devices fabricated without the disclosed aspects.

For example, as illustrated in FIG. 4C, the distance from the source to drain, as indicated by line 426, can be increased (as compared to FIG. 3C). Thus, with the recessed channel structure, the off current can be reduced because the source to drain distance is longer (as compared to the FinFET structure illustrated in FIG. 3C). When local isolation under the gate is recessed, the channel region increases and the gate controllability can also increase.

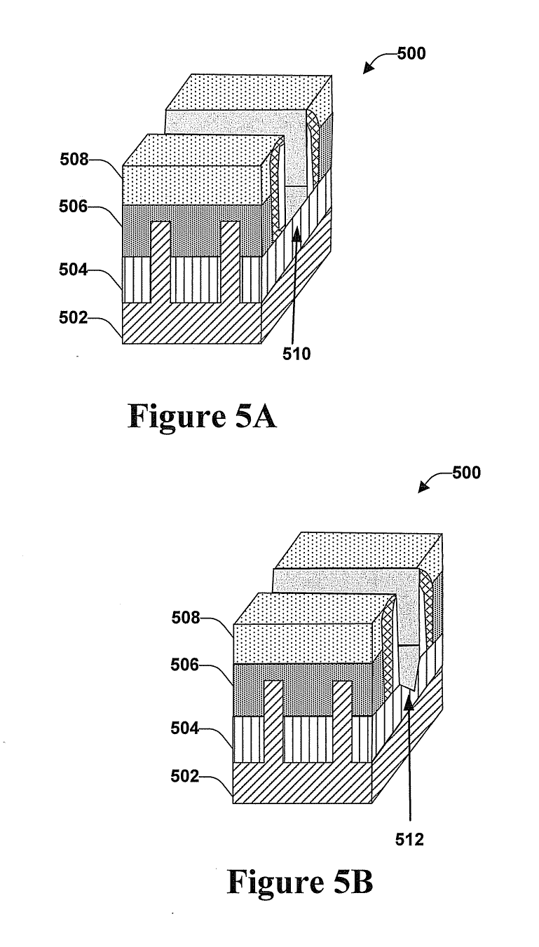

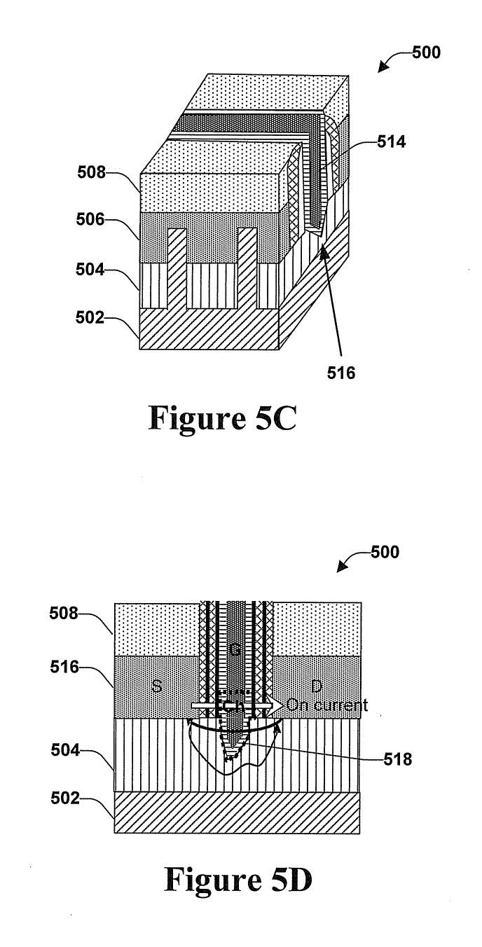

Using the FinFET structure illustrated in FIGS. 3A through 3C and and/or the FinFET structure illustrated in FIGS. 4A through 4C can present some challenges. These challenges will be discussed with reference to FIGS. 5A through 5D, which illustrate a semiconductor structure 500. FIG. 5A illustrates a three-dimensional representation of the semiconductor structure 500 after dummy gate poly removal. Semiconductor structure 500 comprises a silicon substrate 502, a local isolation layer 504, a doped EPI-Si layer 506, and an inter-metal layer dielectric (ILD) layer 508.

The dummy gate poly removal can utilize an ammonium hydroxide (NH4OH) process. During the dummy gate poly removal process, a recess under the gate region, indicated by arrow 510, is desired.

Thus, a Dummy Gate Oxide Removal operation is performed, resulting in the structure illustrated in FIG. 5B. In an example, the Dummy Gate Oxide Removal can be performed using a DHF operation. However, the local isolation recess by a DHF process can produce a variation of recess depth, as indicated by arrow 512. In some cases, the local isolation recess can expose the silicon substrate, as previously discussed.

FIG. 5C illustrates the semiconductor structure 500 after replacement metal gate (RMG) 514 formation. As illustrated at 516, a result of RMG formation can be a variation of channel depth. FIG. 5D illustrates the variation 518 of the channel region.

Thus, as described above, in Bulk FinFET with replacement metal gate (RMG), the recessed channel structure is available due to “intentional” fin isolation recess under the gate region during the RMG process, especially for a DHF treatment for high-k pre-clean. However, there is the risk of isolation recess depth variations, isolation undercut underneath of the spacer, and so forth.

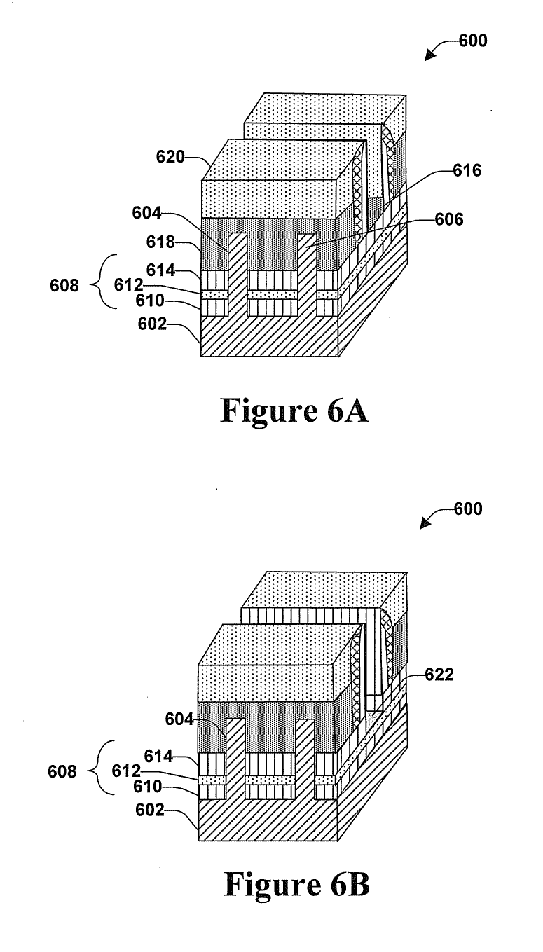

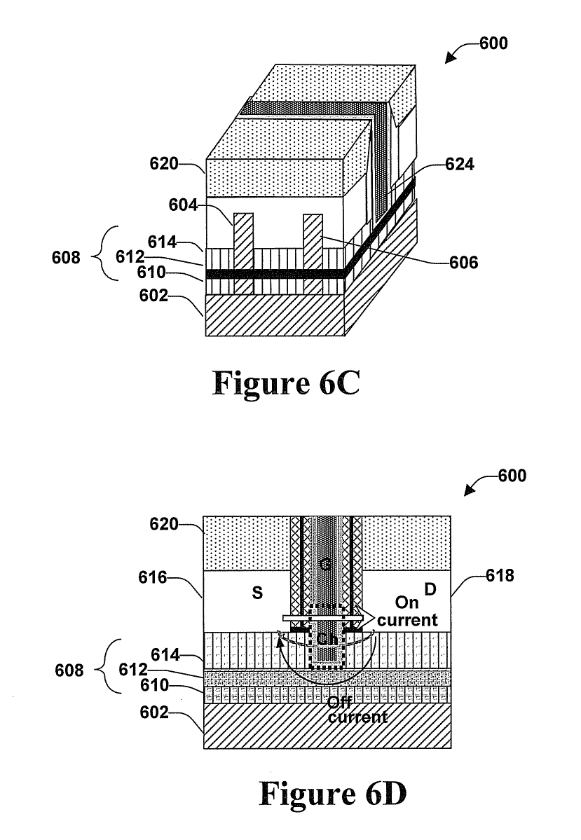

To overcome the aforementioned challenges, FIGS. 6A through 6D illustrate an example, non-limiting schematic representation of a semiconductor structure 600, according to one or more of the disclosed aspects. FIG. 6A illustrates a three-dimensional representation of the semiconductor structure 600 after dummy gate poly removal, according to an aspect. In some cases, the dummy gate poly removal can be performed using an ammonium hydroxide (NH4OH) process.

The semiconductor structure 600 comprises a semiconductor substrate 602 comprising a plurality of fins, illustrated as a first fin 604 and a second fin 606. Also included is a multi-layer structure 608 comprising at least three layers. As illustrated, a first layer 610 is formed on the semiconductor substrate 602. A second layer 612 is formed on the first layer and under a third layer 614 (e.g., the second layer 612 is between the first layer 610 and the third layer 614). Further, the second layer 612 contacts a bottom of a gate dielectric 616. The device can also include a doped EPI-Si layer 618 and an ILD layer 620

In an implementation, the first layer 610 and the third layer 614 comprise a first material and the second layer 612 comprises a second material. In an aspect, the first material and the second material are different materials. For example, the first material can be silicon dioxide (SiO2) and the second material can be silicon nitride (SiN). In an implementation, the first layer, the second layer, and the third layer are local isolation layers.

In some aspects, the first layer and third layer can comprise a first thickness and the second layer can comprise a second thickness, which can be different from the first thickness. For example, the second layer can be thinner than the first layer and the third layer. In another example, the second layer can be thicker than the first layer and the third layer. According to some aspects, the three or more layers can each comprise different thicknesses. In accordance with other aspects, the three or more layers can comprise similar thicknesses.

FIG. 6B illustrates the semiconductor structure 600 after a Dummy Gate Oxide removal process. The removal process can be a DHF process. As illustrated at 622, the channel area is recessed to the second layer 612 (e.g., the third layer 614 is etched away at this portion). Thus, the first layer 610 (e.g., local isolation layer or SiO2 layer is protected by the second layer 612 (e.g., DHF is selective to SiN). FIG. 6C illustrates the semiconductor structure 600 after replacement gate formation, wherein the semiconductor structure 600 comprises a replacement metal gate 624. As illustrated, there is a uniform recess depth and an RMG region.

FIG. 6D illustrates a cross-section representation of the semiconductor structure 600. As illustrated, there is a well defined channel region. The semiconductor device comprises a uniform channel recess depth. The insertion of an additional layer (e.g., a SiN layer, second layer 612) between other layers (e.g., SiO2 layers, first layer 610 and third layer 614) can control the amount of isolation recess since the additional layer (e.g., SiN layer, second layer) can stop the DHF process, for example. Thus, the disclosed aspects can achieve a well controlled recessed channel in a replacement metal gate FinFET.

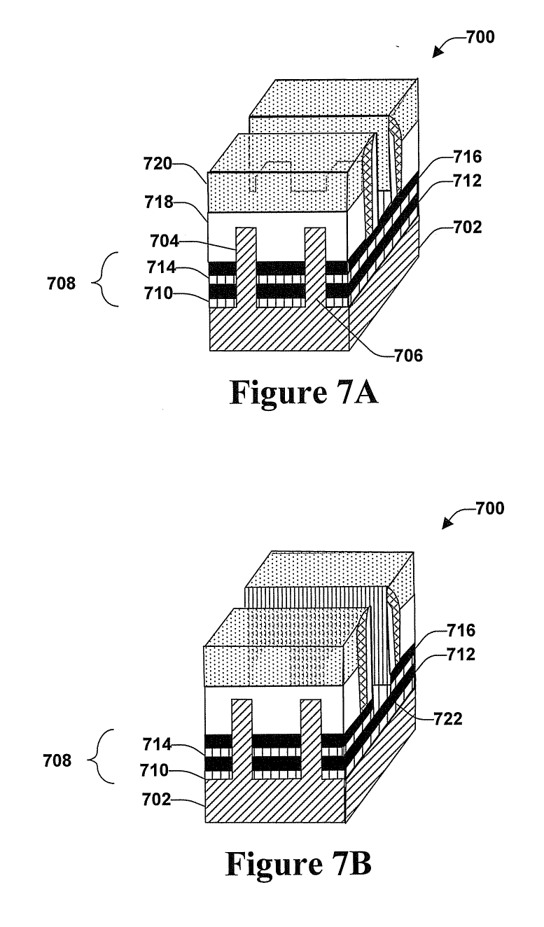

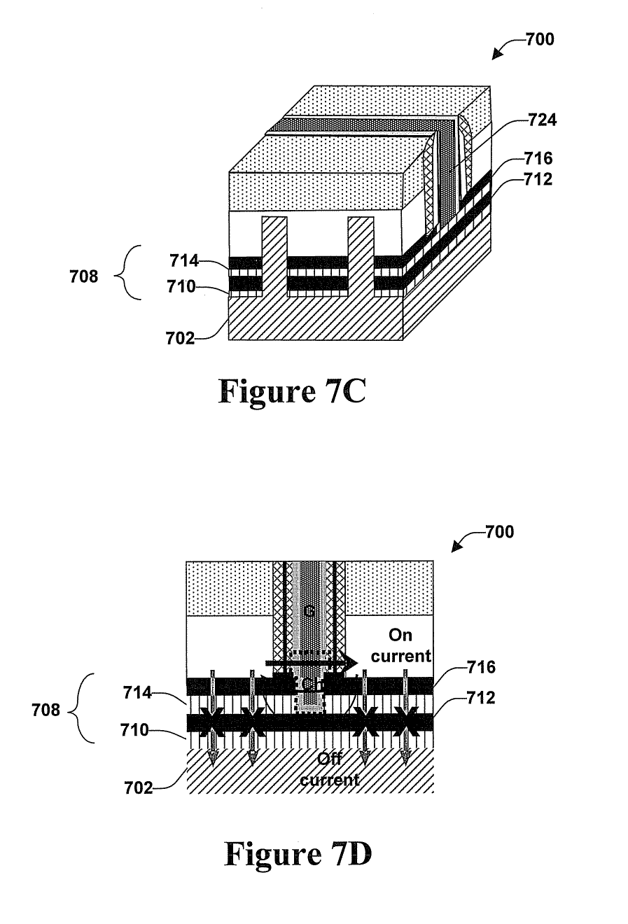

FIGS. 7A to 7D illustrates a semiconductor device 700 that can be fabricated while controlling an isolation recess and to avoid device failures and variations, according to an aspect. The semiconductor device 700 incorporates certain features of the devices illustrated and described with reference to FIGS. 2A through 2D and FIGS. 6A through 6D.

FIG. 7A illustrates the semiconductor device 700 after dummy gate poly removal (e.g., NH4OH). The semiconductor device 700 comprises a semiconductor substrate 702 comprising a plurality of fins, shown as a first fin 704 and a second fin 706. The semiconductor device 700 also comprises a multi-layer structure 708 that includes various layers. For example, the multi-layer structure 708 can comprise a first layer 710, a second layer 712, a third layer 714, and at least a fourth layer 716.

The first layer 710 can be formed over the semiconductor substrate 702. The second layer 712 can be formed on the first layer 710. In an implementation, the second layer can be formed such that the second layer contacts a bottom of a gate dielectric. The third layer 714 can be formed over the second layer and the fourth layer 716 can be formed on the third layer 714. In an implementation, the fourth layer 716 can be formed to contact a bottom of an epitaxial source/drain region 718. An ILD layer 720 can be formed over the epitaxial source/drain region 718.

In an implementation, the first layer 710 and the third layer 714 can comprise a first material and the second layer 712 and the fourth layer 716 can comprise a second material. The first material and the second material can be different materials. For example, the first material can be silicon dioxide (SiO2) and the second material can be silicon nitride (SiN).

FIG. 7B illustrates the semiconductor device 700 after SiN and dummy gate oxide removal, which can be a hot phosphate or DHF operation. As shown at 722, the second layer 712 protects the first layer 710 during the dummy gate oxide removal process. FIG. 7C illustrates the semiconductor device after replacement metal gate 724 formation and FIG. 7D illustrates a cross-section of the semiconductor device 700. Thus, the semiconductor can comprise a controlled recessed channel, wherein one or more of the layers are used for controlling an isolation recess.

Methods that may be implemented in accordance with the disclosed subject matter will be better appreciated with reference to the following flow charts. While, for purposes of simplicity of explanation, the methods are shown and described as a series of blocks, it is to be understood and appreciated that the disclosed aspects are not limited by the number or order of blocks, as some blocks may occur in different orders and/or at substantially the same time with other blocks from what is depicted and described herein. Moreover, not all illustrated blocks may be required to implement the disclosed methods. Those skilled in the art will understand and appreciate that methods could alternatively be represented as a series of interrelated states or events, such as in a state diagram.

It is to be appreciated that the functionality associated with the blocks may be implemented by software, hardware, a combination thereof, or any other suitable means (e.g. device, system, process, component, and so forth). Additionally, it should be further appreciated that the disclosed methods are capable of being stored on an article of manufacture to facilitate transporting and transferring such methods to various devices. In an implementation, the methods disclosed herein can include employing a processor to facilitate execution of code instructions retained in a memory device, the processor, in response to execution of the code instructions, can cause a system to perform various operations as discussed herein.

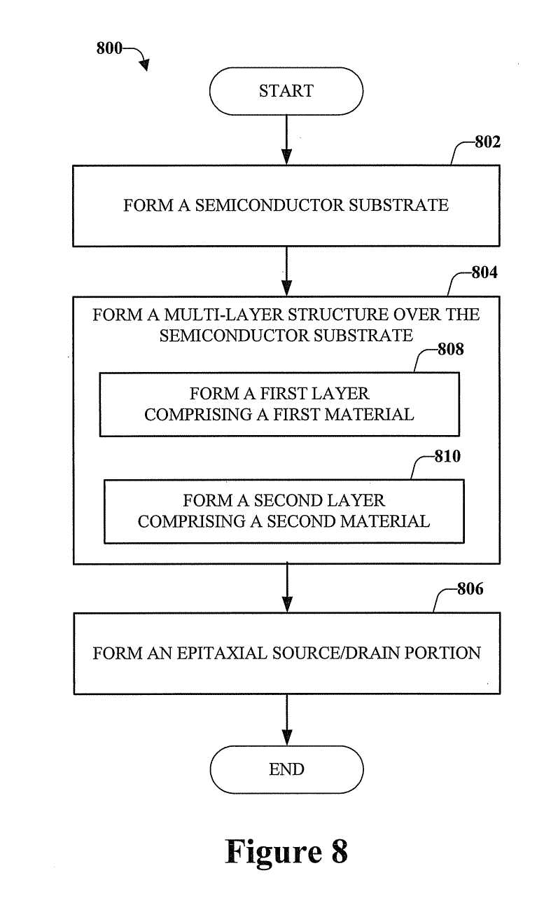

FIG. 8 illustrates an example, non-limiting method 800 for controlling fabrication of a semiconductor device, according to an aspect. At 802, a semiconductor substrate comprising a plurality of fins can be formed. In some aspects, however, the plurality of fins can be formed after the local isolation formation (as will be discussed below).

A multi-layer structure can be formed over the semiconductor substrate at 804 and an epitaxial source/drain portion can be formed at 806. In an implementation, forming the multi-layer structure can comprise forming a first layer comprising a first material at 808. The first layer can be a local isolation layer. A second layer, comprising a second material, can be formed at 810. The second layer can be formed on the first layer. Further, the second layer can be formed such that the second layer contacts a bottom of an epitaxial source/drain portion. In an implementation, the first material can be silicon dioxide (SiO2) and the second material can be silicon nitride (SiN).

In accordance with some aspects, the first layer can comprise a first thickness and the second layer can comprise a second thickness. For example, the first thickness and second thickness can be different thicknesses. For example, the first thickness can be greater than the second thickness. In another example, the second thickness can be greater than (e.g., thicker than) the first thickness. In a further example, the first thickness and the second thickness can be substantially the same size.

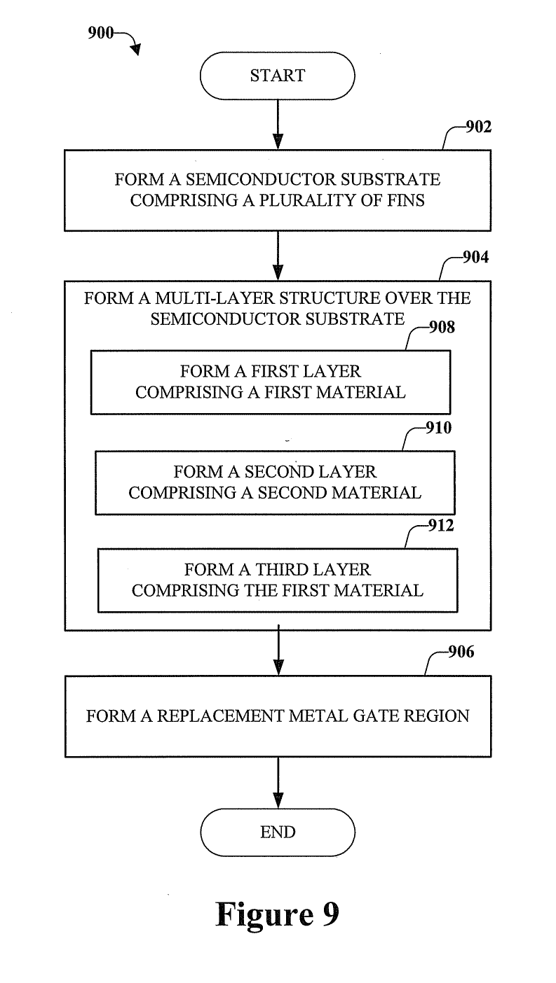

FIG. 9 illustrates an example, non-limiting method 900 for fabricating a semiconductor structure, according to an aspect. The semiconductor structure can be formed such that the semiconductor structure comprises a uniform channel recess depth.

The method 900 starts at 902 when a semiconductor substrate comprising a plurality of fins is formed. However, in some aspects, the plurality of fins can be formed after the local isolation formation. At 904, a multi-layer structure is formed over the semiconductor substrate and a replacement metal gate region is formed, at 906. For example, the semiconductor substrate can be a silicon substrate.

According to an aspect, forming the multi-gate structure can comprise forming a first layer comprising a first material, at 908. A second layer can be formed at 910 and can be formed of a second material. At 912, a third layer comprising the first material can be formed. The first material and the second material can be different materials, in accordance with an aspect. For example, the first material can be silicon dioxide (SiO2) and the second material can be silicon nitride (SIN).

In an implementation, the second layer can be formed between the first layer and the third layer. In another implementation, the second layer can be formed to touch a bottom of a gate dielectric (e.g., the second layer and the bottom of the gate dielectric have no other layers between them). Further, the first layer, the second layer, and the third layer are local isolation layers, according to an aspect.

In accordance with some aspects, the first layer comprises a first thickness, the second layer comprises a second thickness, and the third layer comprises a third thickness. Each of the first thickness, the second thickness, and the third thickness can be different thicknesses. In another example, the three thicknesses can be substantially the same. According to another example, the first thickness and the third thickness are the same thickness.

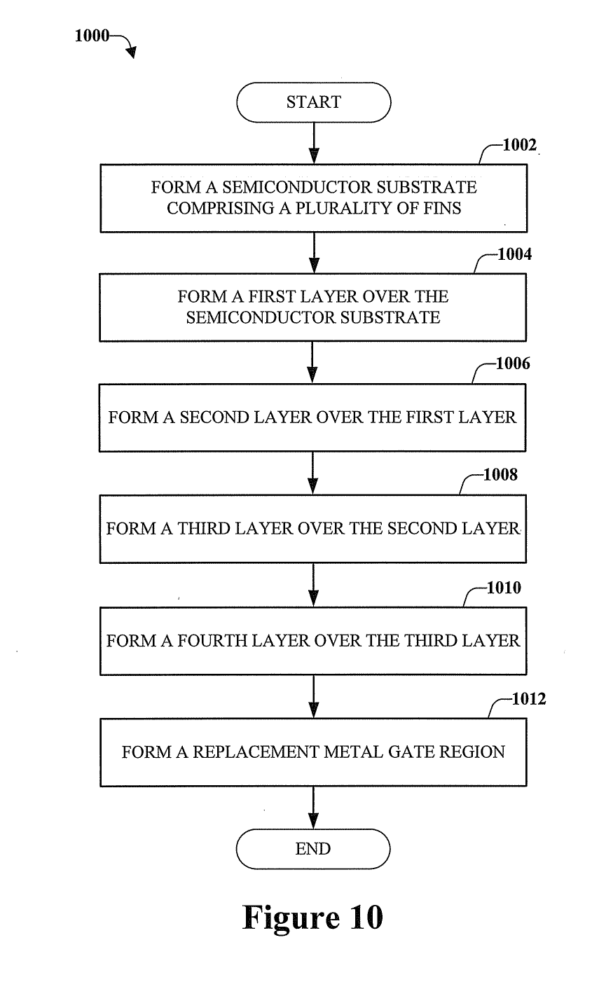

FIG. 10 illustrates an example, non-limiting method for fabricating a semiconductor device while controlling an isolation recess, according to an aspect. Method 1000 starts, at 1002, when a semiconductor substrate is formed. The semiconductor substrate can be, for example, a silicon substrate. At 1004, a first layer is formed over the semiconductor substrate. The first layer comprises a first material.

A second layer is formed over the first layer, at 1006. The second layer can be formed to touch a bottom of a gate dielectric. Further, the second layer comprises a second material, which can be different from the first material. For example, the first material can be silicon dioxide (SiO2) and the second material can be silicon nitride (SiN).

At 1008, a third layer is formed over the second layer. The third layer comprises the first material. At 1010, a fourth layer is formed over the third layer. The fourth layer can be formed to touch a bottom of an epitaxial source/drain region. Further, the fourth layer comprises the second material. The third layer is formed between the second layer and the fourth layer. At 1012, a replacement metal gate region is formed.

In an implementation, forming each of the first layer, the second layer, the third layer, and the fourth layer comprises forming layers that comprise a similar thickness. In another implementation, forming each of the first layer, the second layer, the third layer, and the fourth layer comprises forming layers that comprise different thicknesses.

In some implementations, a plurality of fins can be formed on the semiconductor substrate. Forming the plurality of fins can comprise performing a lithography operation and a first reactive-ion etching operation with a hard mask and four layers comprising alternative layers of tetraethyl orthosilicate (TEOS) and silicon nitride (SiN). Further to this implementation, the method can include implementing a thermal decomposition of tetraethoxysilan (TEOS) operation, wherein a chemical-mechanical planarization operation is stopped by the silicon nitride (SiN) of the hard mask. Further, the method can comprise recessing the TEOS layer by a second reactive-ion etching operation.

According to an implementation, the method can comprise using a second reactive-ion etching operation to strip the silicon nitrate layers of the hard mask. Further, the method can comprise performing a chemical-mechanical planarization operation on the SiN layers, wherein the chemical-mechanical planarization operation is stopped by the TEOS of the hard mask. The method can also comprise recessing the SiN layers using a third reactive-ion etching operation. Further to this implementation, the method can comprise stripping the TEOS of the hard mask with the third reactive-ion etching operation.

In still another implementation, the method can comprise forming local isolation layers and forming at least one fin using a silicon epitaxial operation. Further, the method can comprise removing a silicon nitrite layer included in the local isolation layers.

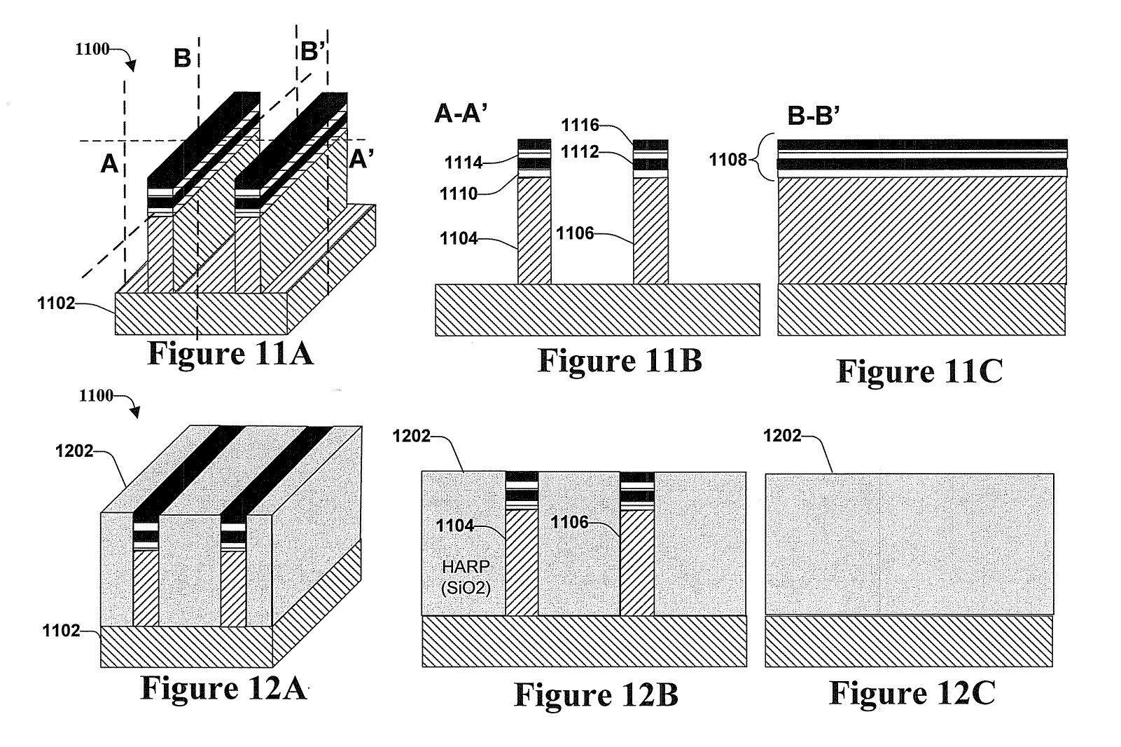

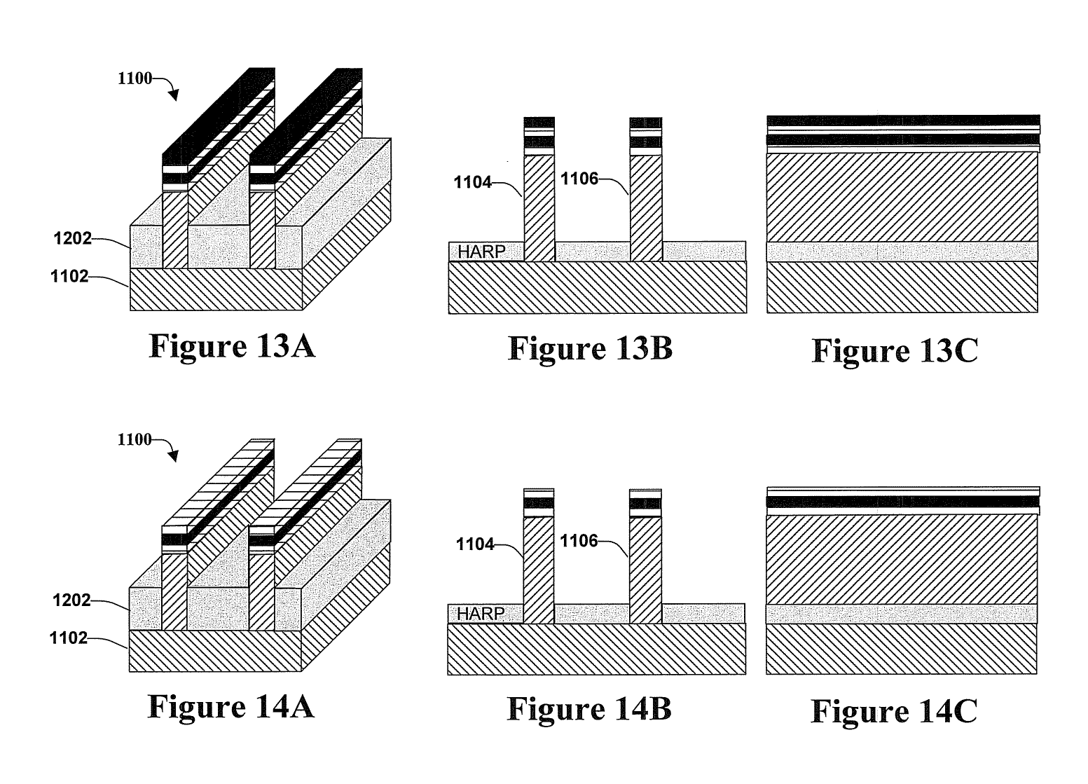

FIGS. 11A through 25C illustrate an example, non-limiting process flow for fabricating a device 1100, which is similar to the semiconductor device 700 shown in FIGS. 7A through 7D, according to an aspect. In the figures, the left figures (e.g., FIG. 11A, FIG. 12A, FIG. 13A, and so forth) depict a three-dimension image of the device 1100. The middle figures, (e.g., FIG. 11B, FIG. 12B, FIG. 13B, and so forth) are cross-sectional representations of the left figure (e.g., FIG. 11A, FIG. 12A, FIG. 13A, and so forth) taken along line A-A′. The right figures (e.g., FIG. 11C, FIG. 12C, FIG. 13C, and so forth) are cross-sectional representations of the left figure (e.g., FIG. 11A, FIG. 12A, FIG. 13A, and so forth) taken along line B-B′.

FIGS. 11A through 11 C illustrate the device 1100 after fin formation, according to an aspect. The device 1100 comprises a silicon substrate 1102, a first fin 1104, and a second fin 1106. It should be understood that, according to various aspects, a device can have more than two fins.

The fin formation can be performed using a lithography and a reactive-ion etching (RIE) operation. The hard mask structure (e.g., the material of the fin) can be a multi-layer structure 1108. The multi-layer structure 1108 can comprise four layers, illustrated as a first layer 1110, a second layer 1112, a third layer 1114, and a fourth layer 1116. The first layer 1110 and third layer 1114 can comprise TEOS (e.g., silicon dioxide). The second layer 1112 and fourth layer 1116 can comprise SiN (e.g., silicon nitride). With the hard mask structure, a stacked sandwiched local isolation can be formed.

FIGS. 12A through 12C illustrate the device 1100 after local isolation deposition. After fin formation with the hard mask, local isolation deposition is performed. In some aspects, HARP (e.g., SiO2) can be used for the local isolation layer 1202. By using a HARP operation, the CMP can be stopped by the silicon nitrite (SiN) on the top of the mask (e.g., the fourth layer 1116) and the local isolation layer (e.g., HARP) can be recessed, as illustrated in FIGS. 13A through 13C.

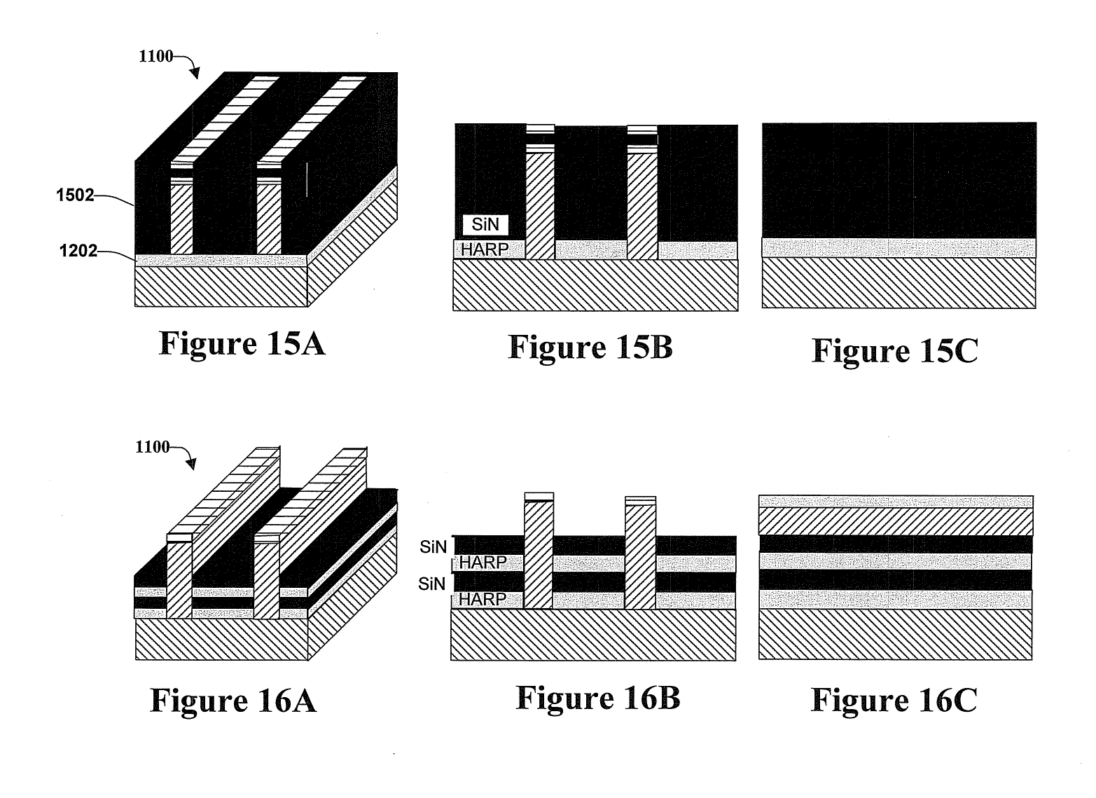

FIGS. 14A through 14C illustrate the hard mask SiN strip process. In an example, the hard mask SiN strip process can be performed using a RIE operation. The fourth layer 1116 (e.g., TEOS hard mark) can help to make the silicon nitrite local isolation (e.g., third layer 1114), similar to the HARP local isolation process. Illustrated in FIGS. 15A through 15C is the device 1100 after SiN deposition. As illustrated, SiN 1502 is grown over the HARP or local isolation layer 1202. The CMP is stopped by the TEOS hard mask (e.g., the third layer 1114).

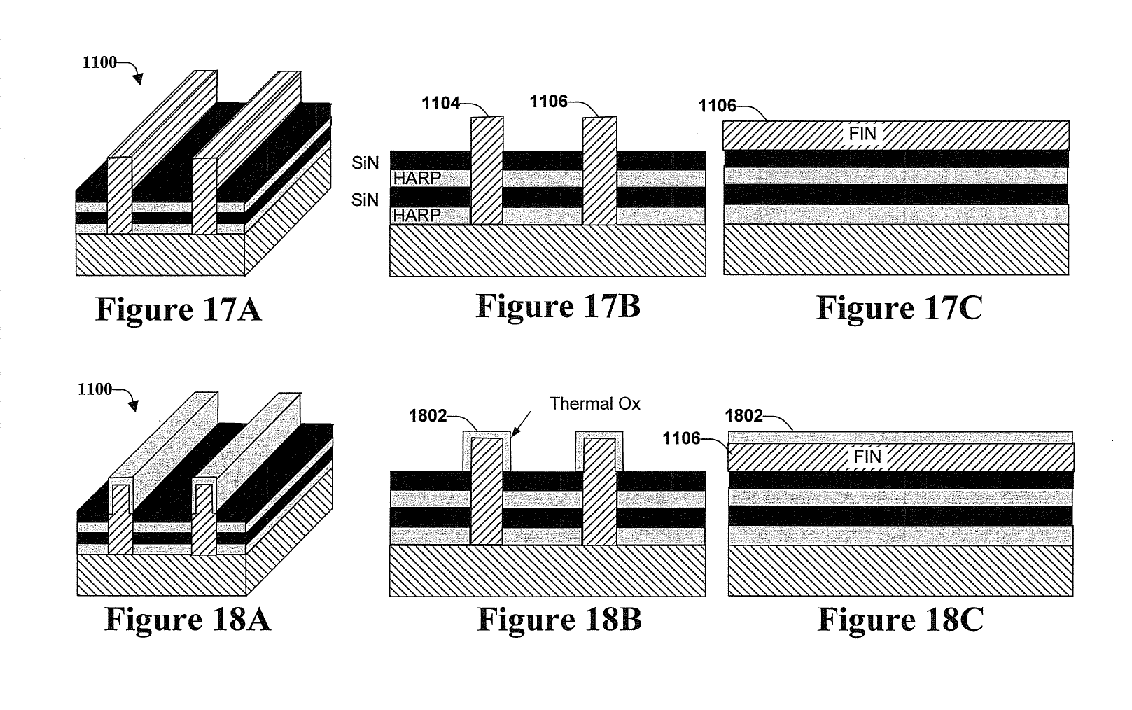

FIGS. 16A through 16C illustrate various operations for fabricating the device 1100. The various operations include SiN recess by RIE, TEOS hard mask stripped by RIE; TEOS deposition; and at least a CMP operation. Since these operations are generally known, further details related to these operations will not be discussed herein for purposes of simplicity. Illustrated in FIGS. 17A through 17C is removal of the last hard mask. In these figures, the TEOS hard mask can be stripped by an RIE operation. This can result in exposure of the fin.

FIGS. 18A through 25C illustrate the remaining processes for fabricating the device 1100. Since various generally known processes can be utilized for the operations illustrated in FIGS. 18A through 25C, details regarding each of the various operations will not be described herein for purposes of simplicity.

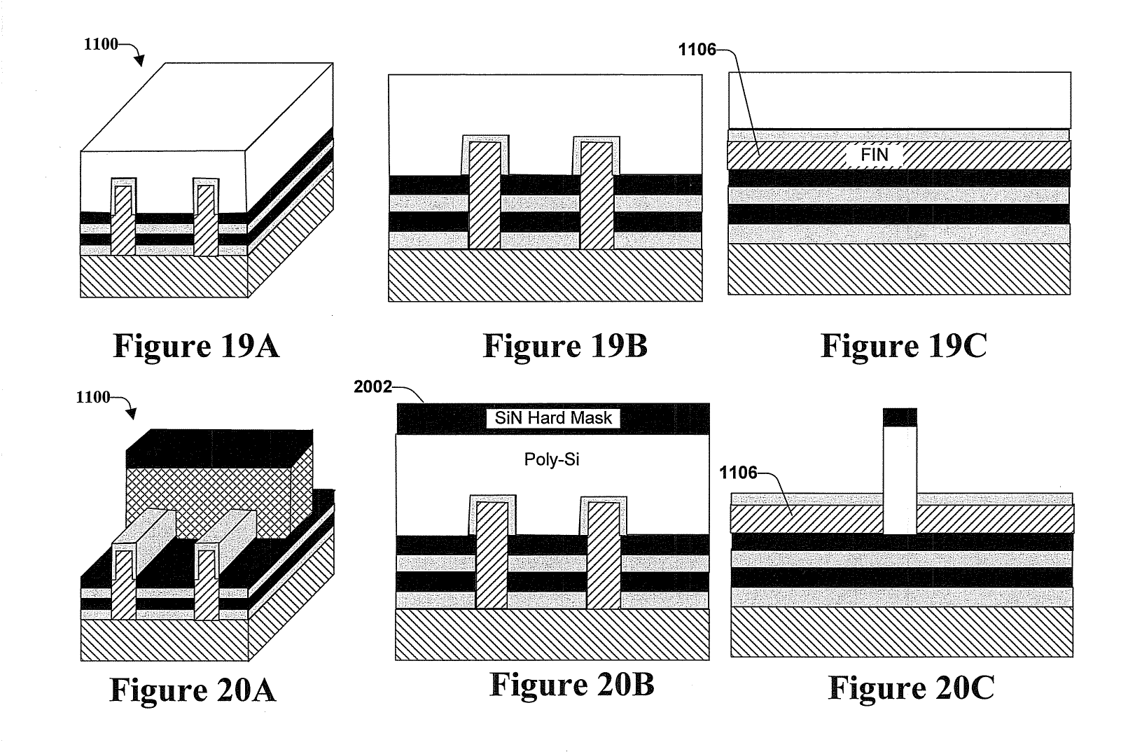

FIGS. 18A through 18C illustrate dummy gate oxide formation. Wherein a thermal oxidation operation can be utilized. FIGS. 19A through 19C illustrate the device after dummy poly deposition.

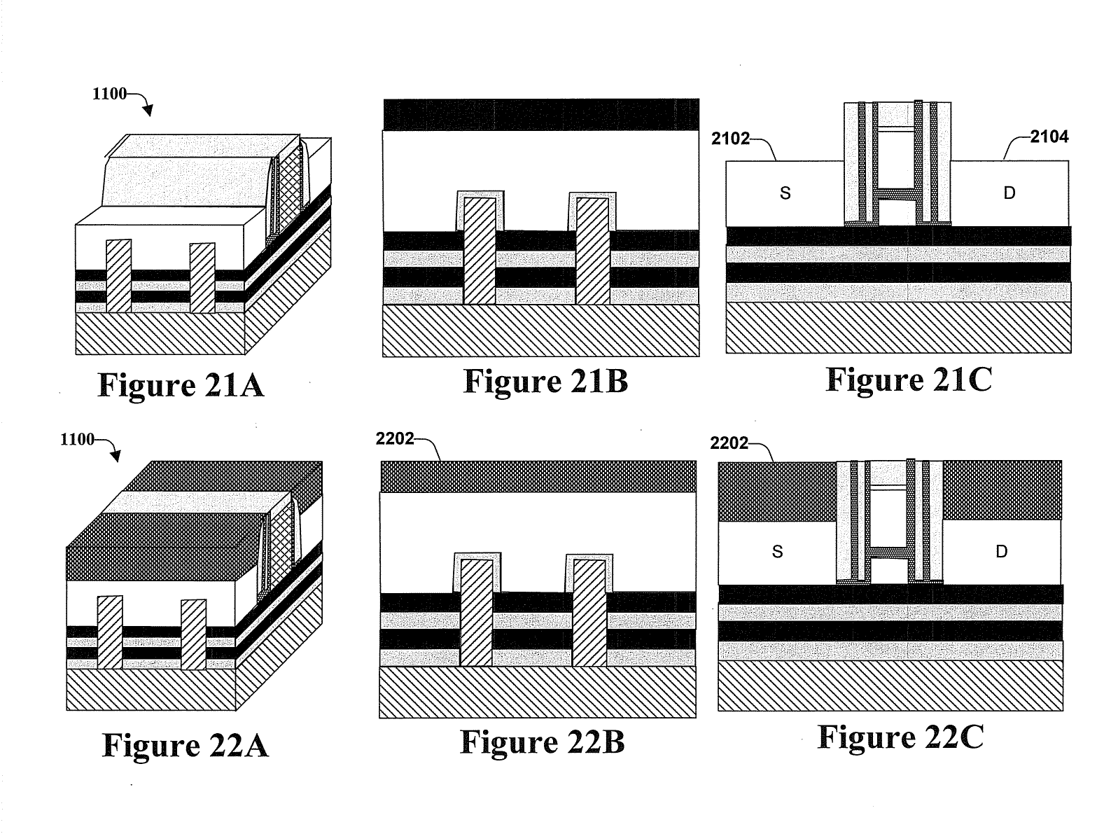

FIGS. 20A through 20C illustrated the device 1100 after dummy gate patterning, hard-mask SiN deposition, gate lithography, and gate RIE operations. FIGS. 21A through 21C illustrate the device 1100 after spacer and source 2102 formation and drain 2104 formation as well as a first TEOS/SiN deposition, RIE, SDE I/I, a second TEOS/SiN deposition, RIE, and in-situ doped S/D-EPI operations.

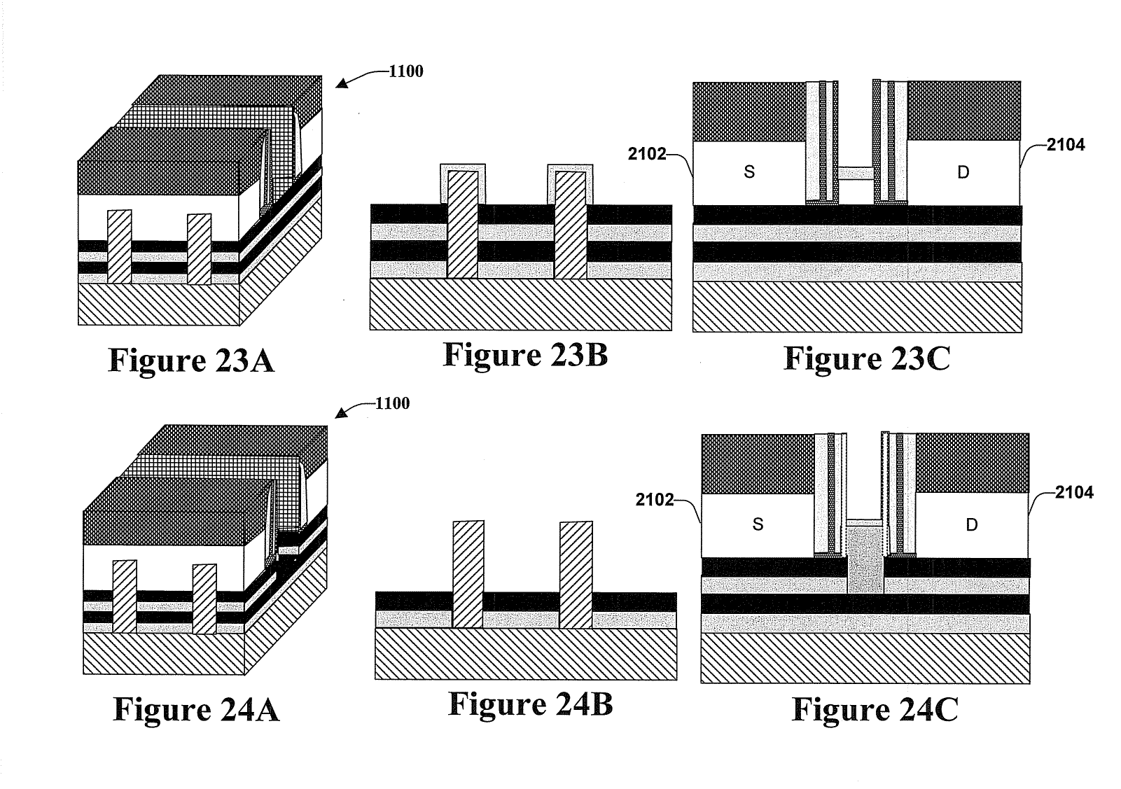

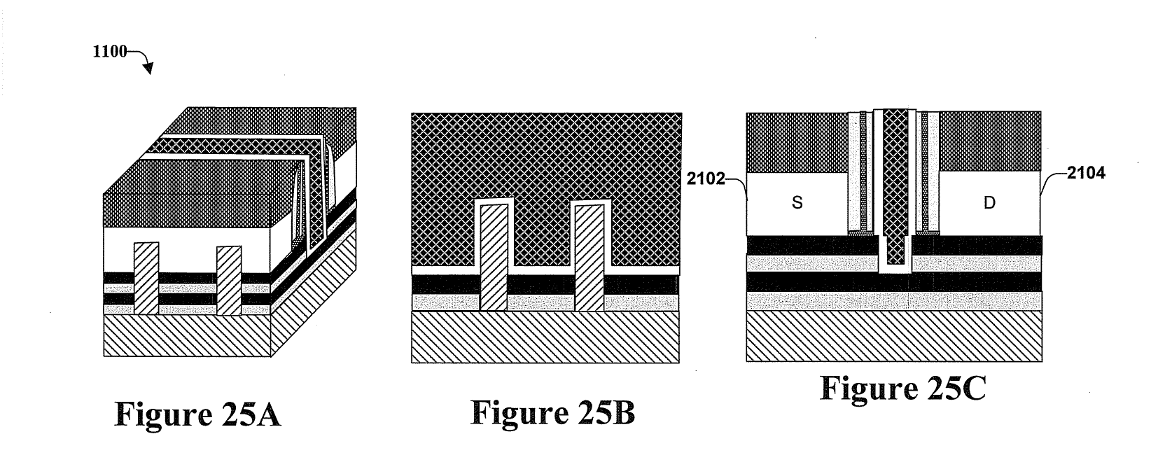

FIGS. 22A through 22C illustrate the device 1100 after ILD formation and Gate open, HARP deposition, and CMP operations. FIGS. 23A through 23C illustrate the device 1100 after hard mask SiN and Dummy Gate removal by hot phosphate, and hot ammonia operations. FIGS. 24A through 24C illustrate the device 1100 after SiN and dummy gate oxide removal and BOX pull down, which can be a hot phosphate or DHF process, which can be stopped by the SiN layer. FIGS. 25A through 25C illustrate the device 1100 after replacement high-k gate dielectric/metal gate formation, high-k gate dielectric deposition, metal deposition, and CMP operations. As discussed since these operations (e.g., processes) are generally known, these processes will not be further discussed herein for purposes of simplicity.

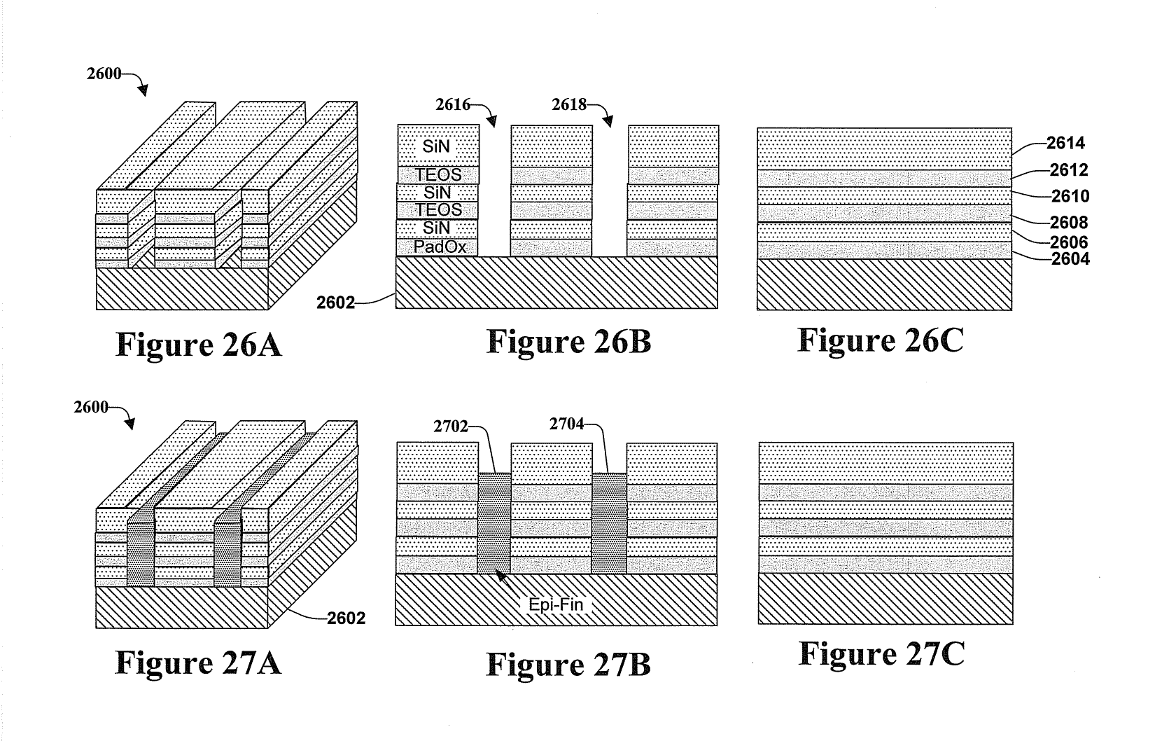

FIGS. 26A through 28C illustrate an alternative process for fabricating a semiconductor device 2600, according to an aspect. FIGS. 26A through 26C illustrate the semiconductor device 2600 after fin hole formation. The semiconductor device 2600 comprises a multi-layer structure. For example, formed on a silicon substrate 2602 can be a first layer 2604 comprising a pad oxide. A second layer 2606 comprising SiN can be formed on the first layer 2604. A third layer 2608 comprising TEOS can be formed on the second layer 2606. A fourth layer 2610 comprising SiN can be formed on the third layer 2608. A fifth layer 2612 comprising TEOS can be formed on the fourth layer 2610 and a six layer 2614 comprising SiN can be formed on the fifth layer 2612. Fin holes are illustrated at 2616 and 2618.

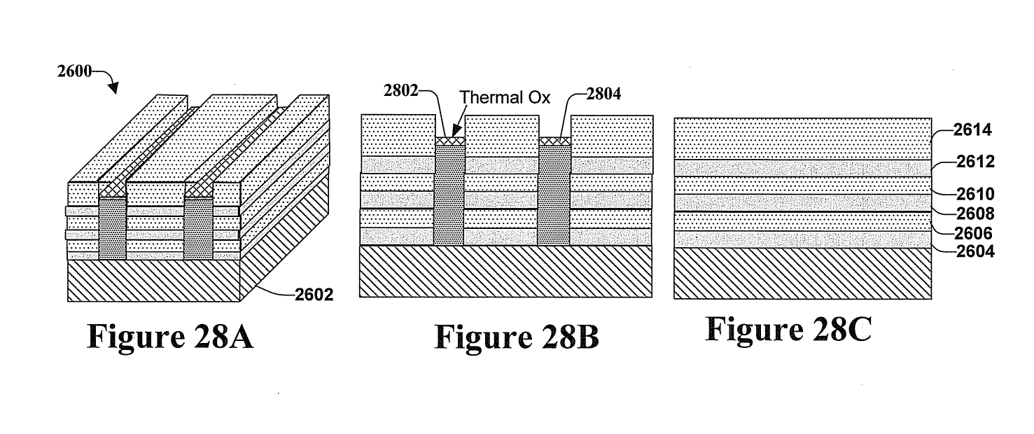

FIGS. 27A through 27C illustrate the semiconductor device 2600 after fin formation and silicon (Si) epitaxial growth. Shown are the EPI-fins 2702 and 2704. FIGS. 28A through 28C illustrate the semiconductor device 2600 after fin top protection. The fin top protection can be achieved through a thermal oxidation process. The thermal oxidation 2802 and 2804 over the fins 2702 and 2704 is illustrated in FIGS. 28A and 28B.

What has been described above includes examples of systems, operations, processes, and/or methods that provide advantages of the one or more aspects. It is, of course, not possible to describe every conceivable combination of components or methods for purposes of describing the aspects, but one of ordinary skill in the art may recognize that many further combinations and permutations of the claimed subject matter are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form.

What is claimed is:

1. A semiconductor structure, comprising:
a semiconductor substrate comprising a plurality of fins;
a multi-layer structure over the semiconductor substrate, the multi-layer structure comprises a first layer and at least a second layer, the first layer comprises a first material and the second layer comprises a second material different from the first material; and
an epitaxial source/drain portion, wherein the second layer is formed on the first layer and contacts a bottom of the epitaxial source/drain portion.

2. The semiconductor structure of claim 1, wherein the first material comprises silicon dioxide (SiO2) and the second material comprises silicon nitride (SiN).

3. The semiconductor structure of claim 1, wherein the first layer and the second layer comprise a similar thickness.

4. The semiconductor structure of claim 1, wherein the first layer comprises a first thickness and the second layer comprises a second thickness, wherein the first thickness is greater than the second thickness.

5. The semiconductor structure of claim 1, wherein the first layer and the second layer are local isolation layers.

6. A semiconductor structure, comprising:
a semiconductor substrate comprising a plurality of fins;
a replacement metal gate region; and
a multi-layer structure over the semiconductor substrate, the multi-layer structure comprises a first layer, a second layer, and at least a third layer, wherein the first layer and the third layer comprise a first material and the second layer comprises a second material different from the first material,
and wherein the second layer is formed between the first layer and the third layer and the second layer contacts a bottom of a gate dielectric.

7. The semiconductor structure of claim 6, wherein the first material comprises silicon dioxide (SiO2) and the second material comprises silicon nitride (SIN).

8. The semiconductor structure of claim 6, wherein the first layer and the third layer each comprise a first thickness and the second layer comprises a second thickness different from the first thickness.

9. The semiconductor structure of claim 6, wherein the first layer, the second layer, and the third layer comprise similar thicknesses.

10. The semiconductor structure of claim 6, wherein the first layer, the second layer, and the third layer are local isolation layers.

11. The semiconductor structure of claim 6 comprises a uniform channel recess depth.

12. A method, comprising:
employing a processor to facilitate execution of code instructions retained in a memory device, the processor, in response to execution of the code instructions, causes a system to perform operations comprising:
forming a semiconductor substrate;
forming a first layer comprising a first material over the semiconductor substrate;
forming a second layer over the first layer, wherein the second layer touches a bottom of a gate dielectric, the second layer comprises a second material, different from the first material;
forming a third layer over the second layer, the third layer comprises the first material;
forming a fourth layer over the third layer, wherein the fourth layer touches a bottom of an epitaxial source/drain region, the fourth layer comprises the second material, wherein the third layer is formed between the second layer and the fourth layer; and
forming a replacement metal gate.

13. The method of claim 12, wherein the first material comprises silicon dioxide (SiO2) and the second material comprises silicon nitride (SiN).

14. The method of claim 12, wherein the forming each of the first layer, the second layer, the third layer, and the fourth layer comprises forming layers that comprise a similar thickness.

15. The method of claim 12, further comprising forming a plurality of fins comprising performing a lithography operation and a first reactive-ion etching operation with a hard mask and four layers comprising alternative layers of tetraethyl orthosilicate (TEOS) and silicon nitride (SiN).

16. The method of claim 15, further comprises implementing a thermal decomposition of tetraethoxysilan (TEOS) operation, wherein a chemical-mechanical planarization operation is stopped by the silicon nitride (SiN) of the hard mask.

17. The method of claim 16, further comprises recessing the TEOS layer by a second reactive-ion etching operation.

18. The method of claim 15, further comprising:
using a second reactive-ion etching operation to strip the silicon nitrate layers of the hard mask;
performing a chemical-mechanical planarization operation on the SiN layers, wherein the chemical-mechanical planarization operation is stopped by the TEOS of the hard mask; and
recessing the SiN layers using a third reactive-ion etching operation.

19. The method of claim 18, further comprising stripping the TEOS of the hard mask with the third reactive-ion etching operation.

20. The method of claim 12, further comprising:
forming local isolation layers;
forming at least one fin using a silicon epitaxial operation; and
removing a silicon nitrite layer included in the local isolation layers.
